(19) United States
(12) Patent Application Publication
(10) Pub. No.: US 2009/0064476 A1
(43) Pub. Date: Mar. 12, 2009

(54) PIEZOELECTRIC MATERIALS BASED ON FLEXOELECTRIC CHARGE SEPARATION AND THEIR FABRICATION

(75) Inventors: L. Eric Cross, State College, PA (US); Wenyi Zhu, State College, PA (US); Nan Li, State College, PA (US); John Y. Fu, State College, PA (US); Nadine B. Smith, Pine Grove Mills, PA (US)

Correspondence Address: GIFFORD, KRASS, SPRINKLE,ANDERSON & CITKOWSKI, P.C, PO BOX 7021, TROY, MI, 48007-7021, US

(73) Assignee: The Penn State Research Foundation, University Park, PA (US)

(21) Appl. No.: 12/179,807

(22) Filed: Jul. 25, 2008

Related U.S. Application Data
(60) Provisional application No. 60/952,375, filed on Jul. 27, 2007.

(51) Int. Cl. H01L 41/24; H01L 41/04

(52) U.S. Cl. 29/25.35; 310/367

(57) ABSTRACT

An example flexoelectric piezoelectric material has a piezoelectric response, which may be a direct piezoelectric effect, a converse piezoelectric effect, both effects, or only one effect. A flexoelectric piezoelectric material comprises shaped elements of a material, which may be a substantially isotropic and centrosymmetric material. The shaped elements, such as cones, pyramids, wedges, or other tapered elements, may provide an electrical response in response to stress or strain gradients due to a flexoelectric effect in the material, and may provide a mechanical response in response to electric field gradients. Examples of the present invention include improved methods of fabricating devices comprising such shaped elements, and multi-layer devices having improved properties.

### REFERENCE TO RELATED APPLICATION

This application claims priority to U.S. Provisional Patent Application Ser. No. 60/952,375, filed Jul. 27, 2007, the entire content of which is incorporated herein by reference.

### GRANT REFERENCE

The invention was supported by the Office of Naval Research (ONR), Grant No. N00014-06-1059. The U.S. Government may have rights in this invention.

### FIELD OF THE INVENTION

The invention relates generally to materials, methods, and devices for generating an electrical signal from an applied stress, or vice versa.

### BACKGROUND OF THE INVENTION

Piezoelectric materials produces a voltage under stress (the piezoelectric effect), and deform under an applied electric field (the converse piezoelectric effect). No material has ever been produced that shows the piezoelectric effect without also having the inverse piezoelectric effect, as the direct and converse effects are thermodynamically identical. Further, the conventional belief is that piezoelectric materials must be non-centrosymmetric, or at least contain a non-centrosymmetric component, which severely limits the material choices available. The most commonly used piezoelectric material is lead zirconate titanate, but there are environmental and public health concerns related to the production and use of any lead-containing material. It has proved difficult to find any better material, using conventional approaches.

Piezoelectric devices have many useful applications, such as high voltage generation (e.g. gas lighters using the resulting spark), microactuators, microbalances, acoustic generators (including ultrasound generators), vibration sensors, and the like. It is impossible in conventional piezoelectrics to break the connection between direct and converse effects. It is also difficult to make either thick or thin film piezoelectrics of high sensitivity. Most current piezoceramics are based on lead containing perovskite structure compositions, and as noted above this is less than ideal. Applications would increase if improved materials were available.

The flexoelectric effect relates to an electric polarization induced by a strain gradient (or equivalently a stress gradient) within a material, and the converse effect is a strain (or stress) in the material induced by an electric field gradient. A flexoelectric material can be centrosymmetric, which under conventional belief would appear to rule out any piezoelectric effect.

The flexoelectric effect is defined by the relationship:

$${P}_{1} = {μ}_{ijkl} ( \frac{\partial {S}_{ij}}{\partial {x}_{k}} ) \qquad ( 1 )$$

where

μᵢⱼₖₗ are the fourth rank polar tensor flexoelectric coefficients,

Sᵢⱼ is the elastic strain components,

Xₖ is the direction of the gradient in S, and

P₁ is the induced electric polarization.

For flexoelectricity (as in piezoelectricity) there is also a converse effect, i.e. there is an elastic stress generated by an electric field gradient defined by the relationship:

$${T}_{ij} = {μ}_{ijkl} ( \frac{\partial {E}_{k}}{\partial {x}_{1}} ) \qquad ( 2 )$$

where

Eₖ is the electric field,

x₁ the direction of the gradient in E, and

Tᵢⱼ the induced stress.

For the direct effect in the MKS system, units for μ are coulombs/meter, and for the converse effect the units are Newton/volt, which are necessarily equivalent as the direct and converse effects are thermodynamically identical.

### SUMMARY OF THE INVENTION

Examples of the present invention relate to improved assembly processes allowing fabrication of high sensitivity multilayer flexoelectric piezoelectric materials, such as ceramics materials. Unlike conventional piezoelectric materials, centrosymmetric materials can be used, allowing a much wider range of materials to be used, and allowing lead-free devices to be readily fabricated. Flexoelectric piezoelectric materials may generate an electric potential in response to an applied force due to the provision of shaped elements within the material. An applied force generates a stress (or strain) gradient within the shaped elements, for example due to a cross-sectional area in a plane normal to the force direction that varies along the force direction. The stress gradient, in combination with the flexoelectric coefficient of the material, induces the electric potential. In such cases, a shaped element of a first material is preferably surrounded by a second material of lesser elastic constant (which may be termed a soft material), so that the stress gradient is not significantly reduced by the presence of the second material. The first material may be a ceramic, and the second material may be a non-ceramic material such as air, a polymer, or some combination of soft materials. Such materials may be used to create improved sensors, and devices for converting mechanical energy (such as vibrational energy) into electrical energy.

In some examples, application of an electric field may induce electric field gradients within a shaped element, for example due to a cross-sectional area in a plane normal to the electric field direction that varies along the field direction. In such cases, a shaped element of a first material is preferably surrounded by a second material of lesser dielectric constant, so that the electric field gradient is not significantly reduced by the presence of the second material. Such configurations can be used to create improved actuators that in some cases do not have the converse sensing capability.

The term flexoelectric piezoelectric effect can be used to distinguish from conventional materials and devices, where the conventional piezoelectric effect or its converse dominates.

In some examples of the present invention, an improved flexoelectric piezoelectric material, and apparatus including such material, comprises a multilayer structure including generally parallel layers of shaped elements. The shaped elements may be pyramids, cones, and the like, or truncated versions thereof. A force (or electric field) may be applied generally parallel to the axes of the shaped elements. For example, the axis of a pyramid or cone joins the center of the base to the vertex, and the axis of a truncated pyramid or cone joins the center of two parallel planar regions (the larger base and the smaller base, where the smaller base is the planar region created by slicing the vertex off the pyramid or cone).

A multilayer structure may include a generally equal number of shaped elements arranged in each of two orientations, a first orientation and a second orientation that is a mirror image of the first orientation (e.g. reflected in a plane parallel to the base). Improved resonance properties are available, as slight variations in the position of the center of mass on application of e.g. an oscillatory force or electrical field can be avoided.

An example flexoelectric piezoelectric material provides a piezoelectric response, which may be a direct piezoelectric effect, a converse piezoelectric effect, both effects, or only one effect. The flexoelectric composite comprises a first material, which may be substantially isotropic, the first material being present in a shaped form. The shaped form gives a piezoelectric response due to a flexoelectric effect in the first material. The shaped form may have ∞m symmetry, or a polar variant of this form such as 4 mm.

In some examples, the composite material has a direct piezoelectric response, the piezoelectric material providing an electrical signal in response to an applied force, the shaped form being chosen so that the applied force induces a stress gradient in the first material, so that the electrical signal arises from a flexoelectric effect within the first material.

In other examples, a flexoelectric composite has a converse piezoelectric response, the material providing a mechanical stress in response to an applied electrical field, the shaped form being selected so that the applied electrical field induces an electrical field gradient in the first material, the mechanical stress arising from a flexoelectric effect within the first material.

A flexoelectric piezoelectric material may comprise first and second materials, the first and second materials having elastic constants differing by at least one order of magnitude, more particularly by more than two orders of magnitude, to facilitate a strong flexoelectric effect at an interface that is at an oblique angle (i.e. not parallel or orthogonal) to the direction of an applied force. In this example, a direct piezoelectric effect is observed, that is enhanced as a stress gradient increases.

In other examples, the first and second materials have electrical permittivities differing by greater than one order of magnitude, more particularly greater than two orders of magnitude. In these examples, a field gradient at an interface that is at an oblique angle (i.e. not parallel or orthogonal) to the direction of an applied field allows a strong flexoelectrically induced converse piezoelectric effect to be observed.

Some composite flexoelectric materials may exhibit an appreciable direct piezoelectric effect, but no appreciable converse piezoelectric effect under the same conditions as which the direct piezoelectric effect is observed. Other composite materials may exhibit an appreciable converse piezoelectric effect, but no appreciable direct piezoelectric effect under the same conditions as which the converse piezoelectric effect is observed. By suitable choice of materials, elastic constant and permittivity properties may be tailored to give direct only, converse only, or both direct and converse piezoelectric effect.

Piezoelectric devices including such piezoelectric materials include sensors (e.g. using a piezoelectric material having a direct effect only), actuators (e.g. using a piezoelectric material having a converse effect only), and the like.

A piezoelectric material may be a composite formed from the first material and a second material, the first material having a shaped form so that an applied force induces a stress gradient in the first material, and/or an applied electric field induces an electric field gradient in the first material, the piezoelectric response arising from a flexoelectric effect within the first material. In some examples, the first material is a ceramic, such as a paraelectric ceramic, in particular a centrosymmetric material in which a conventional piezoelectric effect is not available. Example first materials include barium titanate, barium strontium titanate, and the like.

Example shaped elements within a device may have one or more shaped elements such as a pyramid, truncated pyramid (frustrum), cone, a truncated cone, wedge, and the like. The piezoelectric material may being present in a layer having a thickness less than 100 microns, the shaped elements being generally aligned in a common direction, such as having a central axis generally orthogonal to a substrate. In some examples, a piezoelectric coefficient of greater than 100 pC/N may be obtained for layer thicknesses less than 100 microns.

An example method for preparing a flexoelectric-piezoelectric device comprises providing a template including a negative replica of one or more shaped elements, and forming a assembly including the template and a ceramic precursor, the one or more shaped elements being formed in the ceramic precursor using the template. For example, a ceramic precursor in the form of a green sheet or solid solution may be pressed against the template so as to shape the ceramic precursor, the shaping being carried through into the ceramic after firing, sintering, and/or other processing. The assembly may be thermally treated to remove the template and (possibly in the same process) to convert the ceramic precursor into a ceramic material. The template may be formed from a material that vanishes (e.g. burns off or otherwise vaporizes) during thermal and/or other processing. The template effectively provides a fugitive phase, and a ceramic assembly results including void(s) where the template used to be, prior to thermal processing.

A conducting material, such as a metal or conducting polymer, can be introduced into the void(s), providing electrodes in contact with the shaped element in the ceramic. These electrodes can be used to receive and/or apply an electric signal to or from the shaped elements, relative to another electrode, for example an electrode proximate a base of the shaped elements. The shaped elements are configured so that a force applied across the flexoelectric-piezoelectric material induces a stress gradient within the shaped elements. The flexoelectric-piezoelectric material (or device comprising the material) may have parallel outer surfaces, for example provided by the ceramic used to form the shaped elements, or a coating thereon, across which a force may be applied or detected.

The template may be fabricated by forming a mask by precision machining a replica of the shaped element into a non-ceramic material, such as a plastic, metal, dielectric material, and the like. The composition of the mask is not critical, but machining is facilitated by avoiding the need to machine a hard ceramic material. The mask fabrication may be relatively time consuming and expensive, for example due to the use of a precision machining tool. In some examples of the present invention, one or more masks (for example, a pair of masks, or a mask and a planar element) can be used to forming a mold, allowing the template to be created using the mold, the template including a negative replica of the desired shaped elements. In this way, a single mold can be easily used to make numerous templates, and the templates can be sacrificed during fabrication.

After removal of the template, for example during vaporization during a high temperature thermal process which may also be used to convert the ceramic precursor to a ceramic, voids can form within the ceramic material. The voids can largely define the shaped elements within the material. A conducting material can be introduced into the voids so as to provide an electrical contact. The ceramic precursor may be a green ceramic sheet, and an electrode can be applied to the green sheet before firing of the ceramic.

In some examples, an electrical conductor such as a metal (e.g. a wire or a sheet) can be included in the template. The remaining template material comprises a vanishing or fugitive phase that can be removed, e.g. thermally, leaving the electrical conductor located within a void in the ceramic material (or other material used to form the shaped elements). Further conducting material, such as a molten metal or conducting polymer or precursor thereof (such as a monomer) may be introduced to finalize electrical contact to the shaped elements.

Examples of the present material discuss the use of ceramic materials as the first material used to form the shaped element. However other materials and precursors thereof may also be used.

An example flexoelectric piezoelectric apparatus comprises a first shaped element, configured so as to provide a first stress gradient when a force is applied to the apparatus, and a second shaped element configured so as to provide a second stress gradient when the force is applied to the apparatus. The first and second shaped elements may be configured in a generally mirror-image (e.g. 180 degree rotation) configuration relative to each other, so as to obtain first and second stress gradients that are oppositely directed (i.e. the stress increases in a particular direction in the first element and decreases in the same or parallel direction in the second element). The first shaped element and second shaped element may be pyramids, truncated pyramids, cones, and truncated cones. An example apparatus may comprise a plurality of first shaped elements, and a plurality of second shaped elements. The numbers of first and second elements may be approximately equal, for example a number of truncated pyramids aligned in a given orientation and a similar number aligned in the opposite direction. This allows improved resonance properties of an apparatus, as the device can be configured so that the center of mass does no significantly move in response to applied electric fields or forces, compared with the movement observed in conventional piezoelectric devices.

An example apparatus comprises a central electrode located between the plurality of first shaped elements and the plurality of second shaped elements, an electrical contact (for example, a conducting polymer) to the plurality of first shaped elements, and an electrical contact to the plurality of second shaped elements.

An example flexoelectric piezoelectric apparatus comprises a first plurality of shaped elements, a second plurality of shaped elements, and a central electrode located between the first plurality of shaped elements and the second plurality of shaped elements. For example, the central electrode may be generally planar, with arrays of shaped elements disposed in one or more layers each side of the central electrode. The apparatus may have a pair of generally parallel outer surfaces across which a force may be applied (e.g. in a sensor mode of operation) or generated (e.g. in a transducer mode of operation). The shaped elements may be configured so that a compression applied between the pair of generally parallel outer surfaces induces stress gradients within the first and second plurality of shaped elements. The first (and second) plurality of shaped elements may each comprise shaped elements having opposite orientations.

A method of fabricating a flexoelectric-piezoelectric material, the flexoelectric-piezoelectric material generating an electric potential in response to an applied stress due to a flexoelectric effect, comprises providing a ceramic precursor; shaping the ceramic precursor (for example, by urging against a template); and thermally processing (e.g.) firing the ceramic precursor so as to obtain a shaped ceramic material, the shaped ceramic material being capable of exhibiting a stress gradient when a force is applied across the shaped ceramic material, the stress gradient generating the electric potential. Alternatively, an electric field gradient may occur on application of an electric field, generating forces. The ceramic precursor is a green ceramic, for example being formed using tape casting.

An example apparatus providing an electric potential in response to an applied stress comprises a first surface (such as a planar portion of ceramic material), a second surface (such as a second planar portion of ceramic material), a central electrode, located between the first surface and the second surface, a first flexoelectric piezoelectric layer located between the first surface and the central electrode; and a second flexoelectric piezoelectric layer located between the second surface and the central electrode. A force applied between the first surface and the second surface generates stress gradients within the first and second flexoelectric piezoelectric layers. A flexoelectric piezoelectric layer may include a material, such as a ceramic, shaped to provide a stress gradient on application of the force. Electric potential can then arise from the stress gradients.

An example apparatus providing an electric potential in response to an applied force comprises a material including shaped elements configured so as to provide a stress (or strain) gradient on application of a force to the material (for example, a force between generally parallel outer surfaces), the electric potential arising from the stress gradient within the shaped elements in combination with a flexoelectric effect. The stress gradient may occur due to cross-sectional area variations in a direction parallel to the applied force. The material may be a shaped element formed in a ceramic, and may be a component of a composite. An example apparatus may comprise a first layer, a central electrode, and a second layer, the central electrode being located between the first layer and the second layer, the first and second layers including the shaped elements, shaped so as to provide stress gradient on application of a force to an outer surface of the device, for example a force applied to parallel outer surfaces.

### BRIEF DESCRIPTION OF THE DRAWINGS

FIGS. 1A-1C show forms representing symmetry groups which allow piezoelectricity;

FIGS. 1D-1F show structures having symmetry groups as illustrated in FIG. 1A-1C;

FIG. 2 shows a possible shaped form, in this example a truncated pyramid;

FIG. 3 shows an array of truncated pyramids on a substrate;

FIG. 4 shows an array of truncated pyramids supported by substrate with separation gaps between proximately adjacent pyramids;

FIG. 5A illustrates a configuration used to evaluate piezoelectric materials;

FIG. 5B shows a configuration for d₃₃ measurement;

FIG. 6A illustrates an experiment configuration used to evaluate a shaped form;

FIG. 6B illustrates a truncated rectangular pyramid 90 of barium strontium titanate (BST) used in some experiments;

FIG. 6C shows a photograph of a 3×3 array of BST pyramids on a BST substrate;

FIG. 7 shows a profile obtained by machining a ceramic at micron scale using an insufficiently hard blade;

FIG. 8 further illustrates the effect of flexoelectricity in obtaining a piezoelectric effect; and

FIGS. 9A-9P shows further configurations and approaches.

### DETAILED DESCRIPTION OF THE INVENTION

Example composite materials include a first material having a shape, for example a truncated pyramid. The base shape of a pyramid may be triangular, square, rectangular, or other shape. Other possible shaped elements include a truncated cone, or frustoconical shape. For the first time, such materials were fabricated in the form of truncated pyramid shaped elements of a first material in air. Other example configurations are possible.

An example piezoelectric material comprises formed elements (such as cones, pyramids, prisms, wedges, or other shape providing an oblique surface angled relative to the direction of pressure, and truncated versions thereof) of a first material within a second material. The first material may be an isotropic material having no intrinsic piezoelectric properties in bulk, and the second material may be air. Other examples include formed elements of a first solid material within a second solid material. The term flexoelectric piezoelectric material (or device) may also be used for a material (or device) exhibiting piezoelectric or converse piezoelectric effect largely due to a flexoelectric effect within a material. Flexoelectric piezoelectric materials include materials that do not include any material that is piezoelectric in bulk, the piezoelectric properties arising due to the form of the material(s) used.

An example composite comprises oriented shaped elements of a first material in a matrix comprising a second material, the two materials being elastically dissimilar. In representative examples, the first and second materials are both dielectrics, and in other examples one material may be a fluid such as air. For example, a composite may comprise air-filed conical or pyramidal voids in a solid matrix.

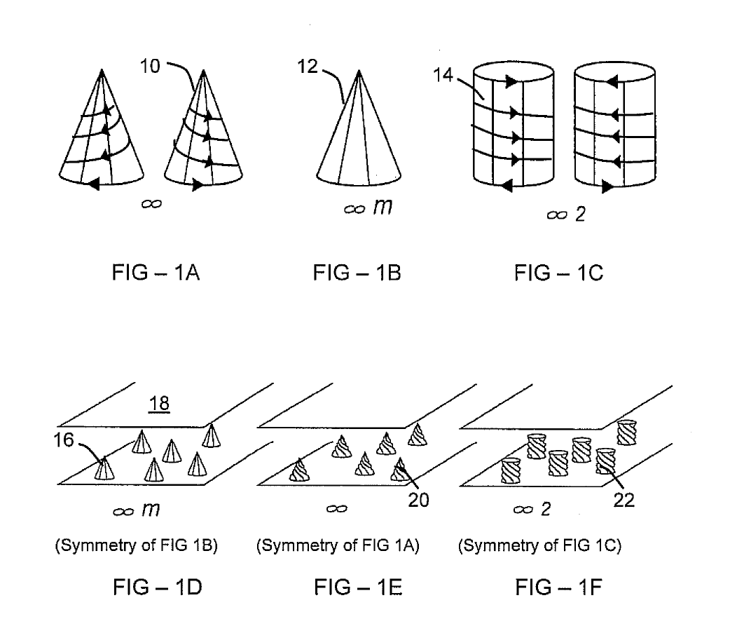

FIGS. 1A-1C show forms representing symmetry groups which allow piezoelectricity, FIG. 1A illustrates the ∞ symmetry at 10, FIG. 1B illustrates the ∞m symmetry at 12, and FIG. 1C illustrates the ∞2 symmetry at 14. These illustrated Curie symmetry groups allow non-zero piezoelectric coefficients. FIGS. 1A and 1C show structures that may exist in right-handed or left-handed forms. Lines top to bottom (apart from edges) are for illustrative purposes only, to suggest three-dimensional structure, and do no correspond to physical structures.

From symmetry considerations, composites of two dissimilar dielectrics made up in the form shown in FIG. 1B have non-zero piezoelectric coefficients, which in matrix notation take the form:

$$\begin{matrix}0 & 0 & 0 & 0 & {d}_{15} & 0 \\ 0 & 0 & 0 & {d}_{15} & 0 & 0 \\ {d}_{33} & {d}_{31} & {d}_{31} & 0 & 0 & 0\end{matrix} \qquad ( 3 )$$

This holds even if both dielectrics are of centric symmetry so that neither is itself piezoelectric. Symmetry alone dictates what must be present at some level, but gives no clues as to the mechanisms responsible for the effects, or whether any of the necessary coefficients will be of useful magnitude.

FIGS. 1D-1F show structures having symmetry groups as illustrated in FIG. 1A-1C, for example cones 16 between substrates such as 18, the structures of FIG. 1D being cones having ∞m symmetry corresponding to FIG. 1B. If such forms are arranged in an orderly manner, as in FIGS. 1D-1F, further showing twisted cones 20 and twisted cylinders 22, to form a two phase composite, and both phases are insulators, even if neither phase is piezoelectric the composite ensemble exhibits some degree of piezoelectricity. Further, if in all groups the so axis is taken as x₃ the matrices of the non-zero piezoelectric constants are as shown in the matrix above.

For the corn symmetry, even if non-piezoelectric materials (in bulk) are used, the two phases differ in elastic properties so that a conical or pyramidal form gives rise to an axial stress gradient, even if the composite is subjected to a uniform stress. The gradient then acts through the flexoelectric effect to produce charge separation.

Symmetry only dictates what is present or absent, and gives no indication as to the magnitude of an effect. Experiments discussed herein demonstrated for the first time that flexoelectricity leads to usable piezoelectric properties in a properly configured composite.

Previous discussions of such symmetry groups, for example J. Fousek, L. E. Cross, and D. B. Litvin, Materials Letters, 39, 287-291 (1999) speculate on the properties of such materials. However, no practical implementation was suggested, nor was there any appreciation that properties far superior to conventional materials, in particular existing lead-free materials, were obtainable. Further, application of stresses is facilitated by truncated forms.

Example composite materials according to embodiments of the present invention include a first material having a shape, for example a truncated cone (frustoconical shape), other shape representing the symmetry of Curie group ∞m as shown in FIG. 1B, or other shape allowing piezoelectric coefficients within an isotropic material. Other examples include a simple 0-3 composite preserving ∞m piezoelectrically active symmetry. Other examples include pyramids (in particular truncated pyramids), and the like. The base shape of a pyramid may be triangular, square, rectangular, or other shape.

An example composite comprises oriented truncated pyramidal or truncated conical shaped elements of a first material in a matrix of a second material, where the two materials are elastically dissimilar. In representative examples, the first and second materials are both dielectrics, and the first or second material may be a fluid such as air.

Oriented shaped elements having at least one surface angled with respect to a force direction in a composite between two elastically dissimilar materials gives rise to gradients in the elastic strain even when subjected to a uniform elastic stress, and experiments showed that this charge separation is due to flexoelectricity. Such a composite may be called a flexoelectric piezoelectric composite, i.e. a composite showing an overall piezoelectric effect that arises from flexoelectric effects within the composite. A flexoelectric piezoelectric composite may be formed entirely from centrosymmetric materials, so the choice of materials is vast compared with conventional piezoelectric material design.

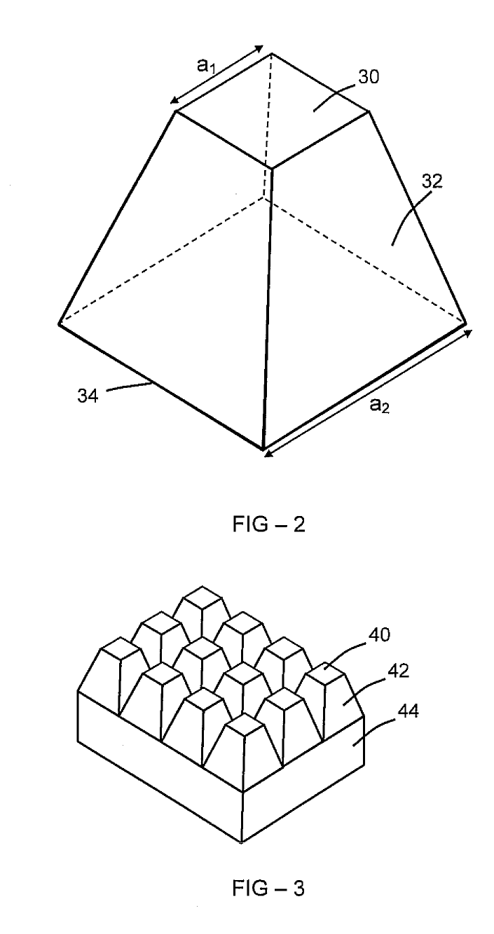

FIG. 2 shows a possible shaped form (or building unit) in the form of a truncated pyramid. The truncated pyramid has a top surface 30, sloping sides 32, and base 34. The base and top surface may be similarly shaped, for example as a square or rectangle. A top surface dimension a₁ and base dimension a₂ are shown. In a square pyramid, the orthogonal dimensions of the top surface and base are also a₁ and a₂, respectively.

Hence, a piezoelectric material is achieved using one or more shaped elements, such as a pyramid, cone, prism (e.g. triangular prism), or other shape, including shaped elements having a base with a larger area than a top surface and at least one side wall having an appreciable angle to the direction of application of force (stress and/or strain). Using smaller dimensions, for example a thickness (or pyramid height, the distance between the top surface and the base) of 250 microns or less, in particular 100 microns or less, remarkably high values of piezoelectric coefficient can be obtained.

FIG. 3 shows an array of truncated pyramids 42 on a substrate 44. A top substrate, not shown for illustrative clarity, may also be used. The pyramids have a top surface 40 having an area less than the area of the base where the pyramid is supported by the substrate 44, so that a stress gradient is developed if a force is applied across the pyramid, e.g. parallel to the central axis. An electrically conducting layer may be disposed along the top and/or sloping sides of the pyramid (or other shape), so as to obtain an electrical potential due to a stress gradient induced flexoelectric effect. In other examples, other shaped elements may be used, e.g. having a variable cross-sectional area measured normal to an applied force so as to provide a stress gradient in any flexoelectric material, such as tapered shaped elements including cones, pyramids, and sections and/or truncations thereof.

The pyramids (or other shaped elements) may abut each other at the base or be separated by a gap. In representative examples, the pyramids may comprise a solid first material such as a ceramic. The second material, generally surrounding the sloping sides of the pyramid, may be a solid or a fluid. In examples studied experimentally, the first material was barium strontium titanate, and the second material was air. In other examples, the second example may be a polymer, such as a polymer generally soft in comparison to a ceramic first material.

The upper surface of the structure, including sides and top surfaces of the pyramids, along with the lower surface of the substrate (upper and lower in reference to the illustrated orientation and not further limiting) may be coated with electrically conducting materials so as to provide first and second electrodes.

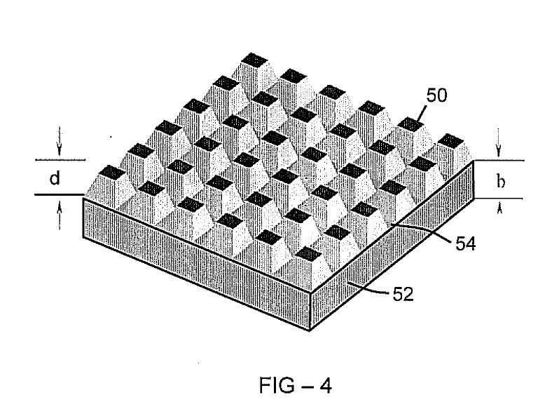

FIG. 4 shows an array of truncated pyramids 50 supported by substrate 52, with separation gaps 54 between proximate pyramids. Here, b is the substrate thickness.

### Material Selection

The flexoelectric coefficients in common dielectrics are small, typically with μᵢⱼₖₗ˜10⁻¹⁰ C/m. However, theoretical studies (e.g. A. K. Tagantsev, Soviet Physics, JETP, 61, 1246, 1985) suggest that in high permittivity dielectrics, the μᵢⱼₖₗ could take the form:

$${μ}_{ijkl} = γ {χ}_{kl} ( \frac{e}{a} ) \qquad ( 4 )$$

where

γ is a constant of order unity,

Xₖ₁ is the dielectric susceptibility,

e is the electric charge in the unit cell, and

a is the unit cell dimension.

This suggests that much higher μᵢⱼₖₗ can be achieved in a soft mode ferroelectric like dielectrics, and this has been verified experimentally, for example as discussed in W. Ma, and L. E. Cross, Appl Phys. Lett. 82, 3293, (2003).

Surprisingly, lead based compositions like lead zirconate titanate (PZT), which are excellent piezoelectrics, have γ almost one order smaller than barium based compositions like BST and BaTiO₃. Hence, flexoelectric piezoelectric ceramics can be lead free without compromising performance.

In barium strontium titanate (Ba_{0.67}Sr_{0.33})TiO₃, μ₁₁ is approximately 100 μC/m, some 6 orders larger than the typical values for conventional common dielectrics. Experiments confirmed that μ₁₁ measured by both direct and converse methods for BST are identical within experimental error.

Example materials which may be used as materials in a flexoelectric piezoelectric include oxides, such as titanates, in particular barium titanate, strontium titanate, barium strontium titanate (BST), other titanates, and other oxides. Example materials include high-K ceramics. Example materials include compounds of barium, compounds of strontium, compounds of zirconium, and the like. In other examples, polymers may be used as one or both of the components of a flexoelectric piezoelectric composite.

Other paraelectric perovskite structure ceramics have large values of flexoelectric coefficients μ₁₁, μ₁₂, and are good choices for a material used in a piezoelectric composite.

### Fabrication and Characterization of a Flexoelectric Composite

A piezoelectric material was fabricated, and piezoelectric measurements obtained, for a millimeter scale flexoelectric piezoelectric composite designed to have an easily measurable piezoelectric coefficient d₃₃, and an easily calculable d₃₃ response, induced by a flexoelectric origin, from the known flexoelectric and elastic properties of the constituent phases. The existence of a measured piezoelectric response was demonstrated, and showed experimental evidence that the charge separation mechanism involved is flexoelectricity.

A flexoelectrically driven piezoelectric composite was constructed from barium strontium titanate (BST) and air. Both components of the piezoelectric composite are centric dielectrics, the first time a piezoelectric material has been made without a non-centrosymmetric component. The material has appropriate shaped internal surface configurations such as illustrated in FIG. 1. The material demonstrated a clear piezoelectric signal as measured on a conventional Berlincourt d₃₃ meter.

Barium strontium titanate was chosen as strong flexoelectric component, Ba_{0.67}Sr_{0.33}TiO₃. To generate a strong S₃₍₁₎ strain gradient, a close packed 3×3 array of millimeter scale square truncated pyramids was cut into the flat face of a BST ceramic sheet. The pyramid surfaces and the obverse side of the BST sheet were sputter coated with gold electrodes, and a robust stress distributing brass electrode was mounted on the upper surface of the pyramid array with conductive silver epoxy. Hence, a practical piezoelectric demonstrator was fabricated from BST ceramic at the (Ba_{0.67}Sr_{0.33})TiO₃ composition, which had a measured μ₁₁=120 μC/m at 25° C.

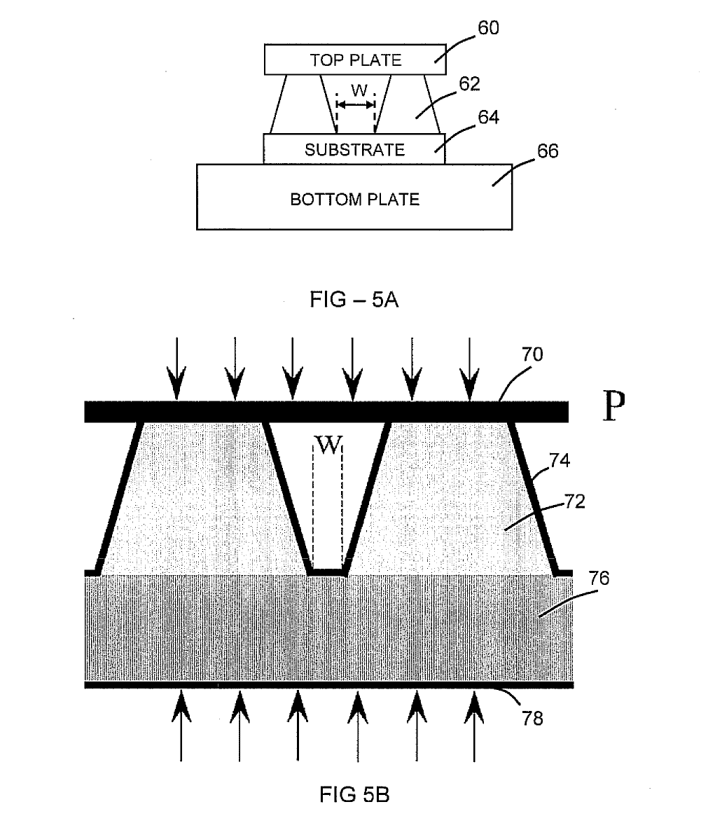

FIG. 5A illustrates a configuration used to evaluate piezoelectric materials. The configuration shown includes top plate 60, piezoelectric material comprising pyramidal shaped elements 62, substrate 64, and bottom plate 66.

For converse piezoelectric effect evaluation, the top and bottom plates both comprised polished glass, and a laser interferometric method was used to detect dimension changes on application of an electric field. The optional substrate 64 may comprise the same material as the pyramids 62, or otherwise be used for growth, formation, and/or support of the pyramids.

For direct piezoelectric effect evaluation, the top and bottom plates were pressure surfaces such as metal, and were used to apply stress to the piezoelectric materials, with electrical signals detected between electrodes in contact with the base and top surface and sides of the pyramid shaped elements.

FIG. 5B shows a configuration for d₃₃ measurement, using a top metal plate 70, pyramids (in cross-section) 72, upper electrode 74 shown as a thick black line, substrate 76, and lower electrode 78. The arrows indicate application of stress.

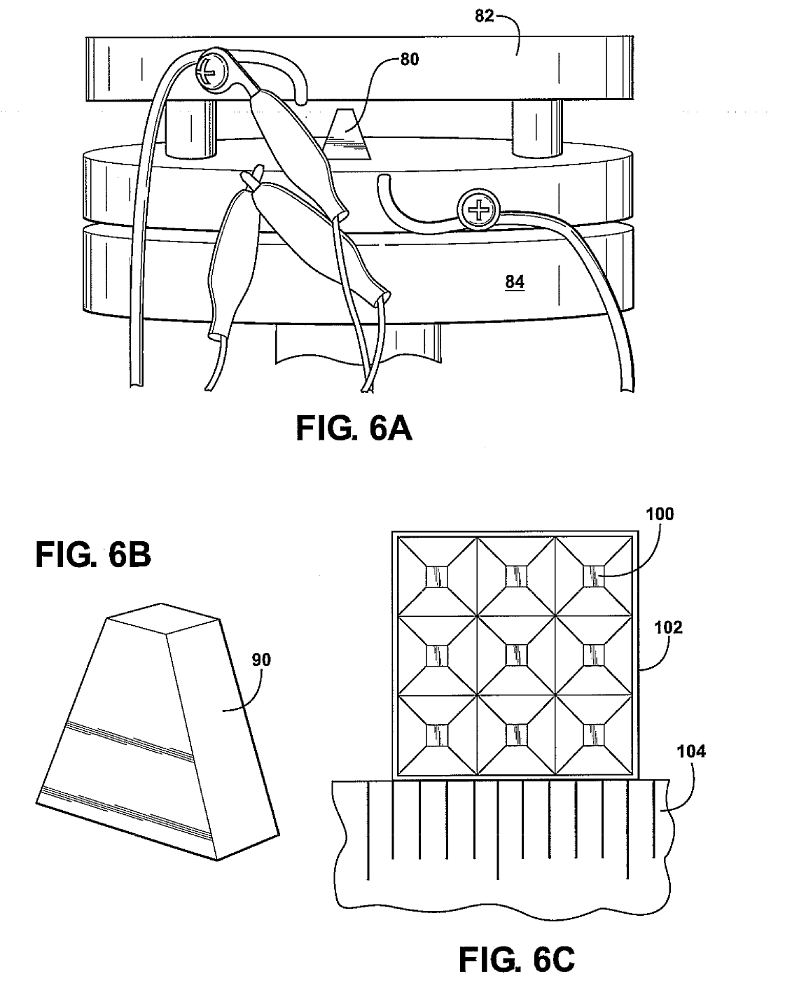

FIG. 6A illustrates an experiment used to evaluate a pyramidal shape 80, between upper and lower pressure plates 82 and 84 respectively.

FIG. 6B illustrates a truncated rectangular pyramid 90 of barium strontium titanate used in some experiments.

FIG. 6C shows a photograph of a 3×3 array of BST pyramids 100 machined from a 1.28 mm thick block, leaving a 0.52 mm thick BST substrate 102. The top view of the structure was photographed against a millimeter scale 104. For experiments with this structure, for uniform stress distribution a 1 mm thick brass plattern covered the upper face. (A metal plate may be used as a force receiving surface or actuator component.) Since under uniform applied stress the axial strain gradient extends down the slanting pyramid faces, the whole upper surface was electroded with sputtered gold.

For piezoelectric measurements, a piezoelectric material was placed between the contacts of a standard Berlincourt d₃₃ meter (model ZJ-2), which uses an elastic drive signal at 100 Hz and compares the piezoelectric output to that of a built in PZT standard. To establish the confidence level a rectangular block of BST at the same composition was measured in the d₃₃ meter yielding the value 0.4 pC/N.

An experiment was performed with a material as shown in FIG. 6C, using the set-up of FIG. 5B, having a 3×3 array of truncated pyramids having dimensions a₁=1.13 mm, a₂=2.72 mm and pyramid height, d=0.76 mm, The gap spacing W was 190 microns. The materials were evaluated for up and down orientations of the pyramids in the Berlincourt meter, giving values of d₃₃ of 6.0 and 6.3 pC/N respectively. The differences may be due to different stress distributions in the two experimental configurations. These results were corrected for capacitance effects. The temperature was 24° C., where BST was in the paraelectric state.

Assuming flexoelectricity as the origin of the piezoelectric response, the relation between d₃₃ and μ₁₁ for an axial stress gradient in the composite takes the form

$${d}_{33} = \frac{{μ}_{11} {∇}_{3} {T}_{3}}{{c}_{11} {T}_{3}^{1}} \qquad ( 5 )$$

where

∇₃T₃ is the axial stress gradient in the ceramic,

T₃¹ the uniform axial stress applied to the composite, and

C₁₁ the elastic constant of the ceramic.

Using a finite element method to calculate the gradient, a calculated d₃₃=6.0±1 pC/N was determined for the same sample. The experimental results proved that the composite is piezoelectric, in spite of the fact that all component elements are centric, which forbids piezoelectricity unless the shape has special symmetry forms discussed above in relation to FIG. 1A-F. This is the first time such a composite has been made. The agreement of experimental and theoretical results confirms that flexoelectricity is the origin of the observed piezoelectric effect in these materials.

### Enhanced Piezoelectric Effect at Small Dimensions

A dramatic enhancement of the piezoelectric effect is possible at smaller dimensions. For example, using a square truncated pyramid as the element in a composite, the upper square face has a side of length a₁, and the base dimension length is a₂, as shown in FIG. 2. In this example, the side wall 32 is configured so that a₂ is a linearly increasing function of d, the depth from a₁ to a₂. For a force F applied normal to the upper and lower surfaces, the stress in the upper surface will be T₃₍₁₎=F/a₁² and will give rise to a strain S₃₍₁₎ given by S₃₍₁₎=F/a₁²c₁₁, where c₁₁ is the elastic constant of the truncated pyramid.

Similarly for the lower surface, T₃₍₂₎F/a₂², giving rise to a strain S₃₍₂₎ given by S₃₍₂₎=F/a₂²c₁₁.

Since the side walls are configured to make a₂ a linear function of d,

$$\frac{\partial {S}_{3}}{\partial d} = \frac{{S}_{3 ( 1 )} - {S}_{3 ( 2 )}}{d} = \frac{F ( \frac{1}{{a}_{1}^{2}} - \frac{1}{{a}_{2}^{2}} )}{d {c}_{11}} . \qquad ( 6 )$$

If the pyramid material has a flexoelectric coefficient μ₁₁, then

$${P}_{3} = {μ}_{11} \frac{\partial {S}_{3}}{\partial {d}_{3}} = {μ}_{11} \frac{F ( \frac{1}{{a}_{1}^{2}} - \frac{1}{{a}_{2}^{2}} )}{d {c}_{11}} = {μ}_{11} \frac{\frac{{a}_{2}^{2} - {a}_{1}^{2}}{{a}_{1}^{2}}}{d {c}_{11}} \cdot \frac{F}{{a}_{2}^{2}} \qquad ( 7 )$$

i.e.,

$${P}_{3} = {μ}_{11} \frac{( \frac{{a}_{2}^{2} - {a}_{1}^{2}}{{a}_{1}^{2}} )}{d {c}_{11}} {T}_{3} \qquad ( 8 )$$

but for a piezoelectric sheet:

P₃=d₃₃T₃, (9)

so that:

$${d}_{33} = {μ}_{11} \frac{( \frac{{a}_{2}^{2} - {a}_{1}^{2}}{{a}_{1}^{2}} )}{d {c}_{11}} \qquad ( 10 )$$

For BST at room temperature μ₁₁˜100 μC/m, and c₁₁=1.66×10¹¹ N/m. For a₁=50 μm, a₂=250 μm, d=250 μm, then d₃₃≈60 pC/N. Scaling down, for example, a₁=5 μm, a₂=25 μm, d=25 μm, and then d₃₃=600 pC/N. This value is remarkably high, and achieved with readily achieved dimensions.

Because they are gradient driven, the piezoelectric coefficient d₃₃ will increase linearly with decreasing composite thickness (i.e. pyramid height, d), for example:

| | |
|---|---|
| Millimeter scale | 6 pC/N |
| 100 μm scale | 60 pC/N |
| 10 μm scale | 600 pC/N |
| 1 μm scale | 6,000 pC/N |

These are representative values, which vary with material and exact configuration, Macro-scale device thicknesses can be obtained using a multilayered micron-scale thickness layers.

In conventional composites piezoelectrics the piezoelectric activity decreases markedly as the dimensions are reduced into the micron range. Both thick and thin film materials have reduced dᵢⱼ constants. In the flexoelectric piezoelectric materials according to embodiments of the present invention, because charge separation is gradient driven, activity increases as the dimensions are reduced.

For a square pyramid, the uniform stress gradient T₃₍₁₎ steepens with decreasing scale as 1/d, where d is the pyramid height. Hence, for a BST flexoelectric piezoelectric composite, a value of d₃₃ comparable to that of lead zirconate titanate is expected to be at the micrometer scale.

Two composites were fabricated to have a form as shown in FIG. 4. For the first composite, the pyramid height d and substrate thickness b were both 50 microns, and the gap spacing between pyramids was 29 microns (“W” in FIG. 5). For the second composite, pyramid height and substrate thickness were both 100 microns, and gap spacing was 28 microns. Preliminary results for the converse piezoelectric effect, using polished glass top and bottom plates and an interferometric technique, indicated d₃₃˜50 pC/N for the first composite and 25 pC/N or the second composite. The profile of the second ceramic, shown approximately at 120 in FIG. 7 on substrate 122, do not curve in the desired manner due to bending of the cutting blades (designed for biological materials) in the ceramic. However, these results show the general trend expected from theory, showing that piezoelectric coefficient greater than 100 pC/N may be obtained using device structures having dimensions in the tens of microns.

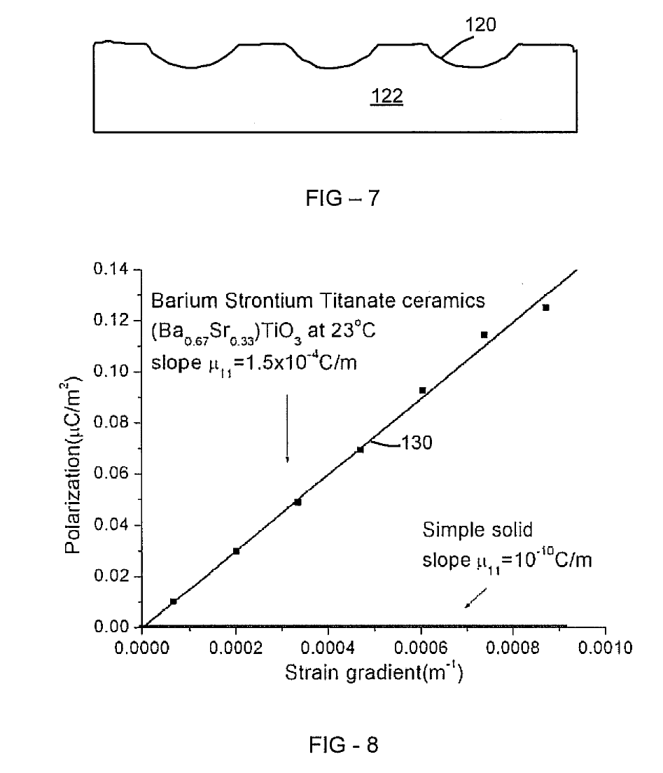

FIG. 8 further demonstrates the effect of flexoelectricity in obtaining a piezoelectric effect, showing a generally linear dependence (130) of strain gradient against polarization. Strain gradients can be obtained using the described shaped forms, and also through bar-bending experiments for evaluation purposes.

### Further Example Configurations and Fabrication Methods

Novel approaches for the fabrication of high gradient micro-pyramid structures for macro-scale flexoelectric piezoelectric composites were developed. In some examples, the devices may be self aligning during fabrication.

Novel approaches are described for fabricating multilayer high gradient flexoelectric composites which automatically preserves element alignment (e.g. micro-pyramid alignment) and permits the fabrication of bulk ceramics which preserve the high gradient feature of earlier produced thick film systems.

Example techniques are related to ceramic tape casting techniques, which have been used for the fabrication of multilayer ceramic capacitors. Tape thicknesses down to 1 μm thickness are commercially achievable by the larger capacitor producers in units incorporating more than 1,000 layers.

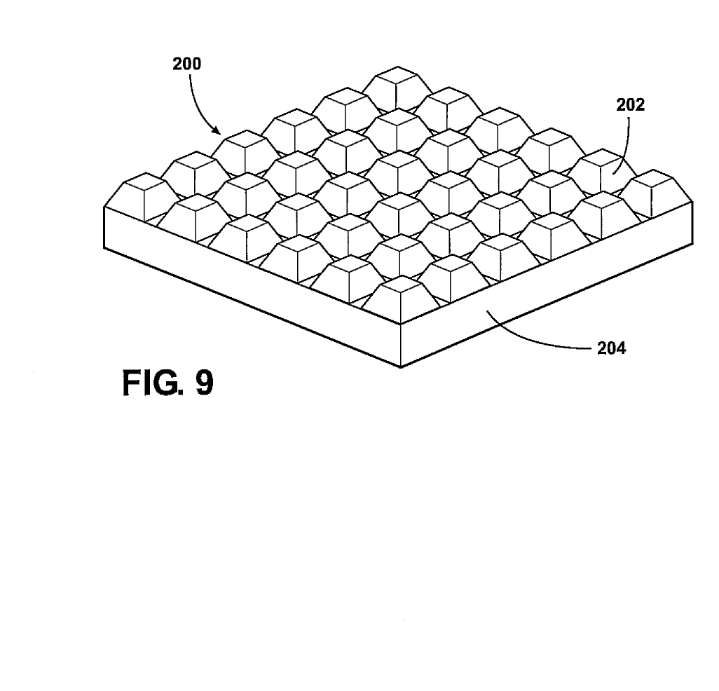

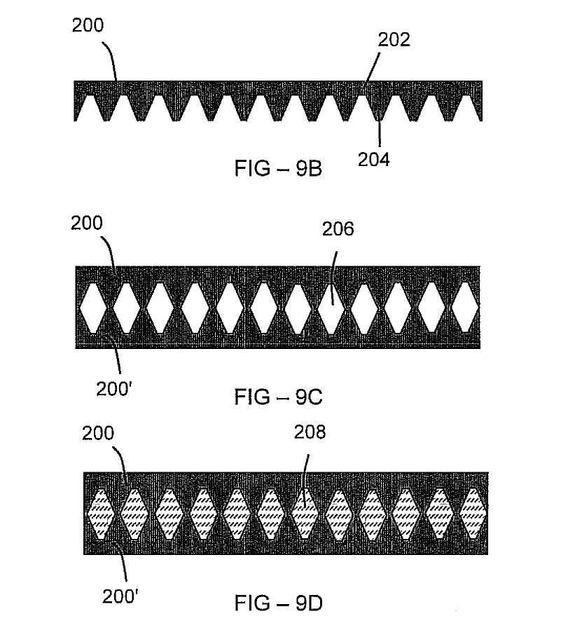

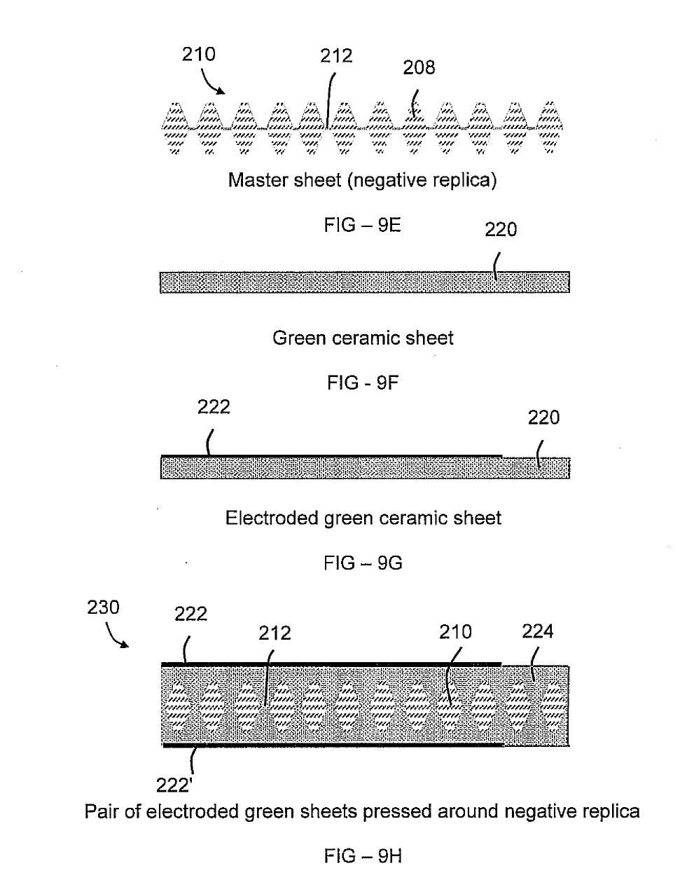

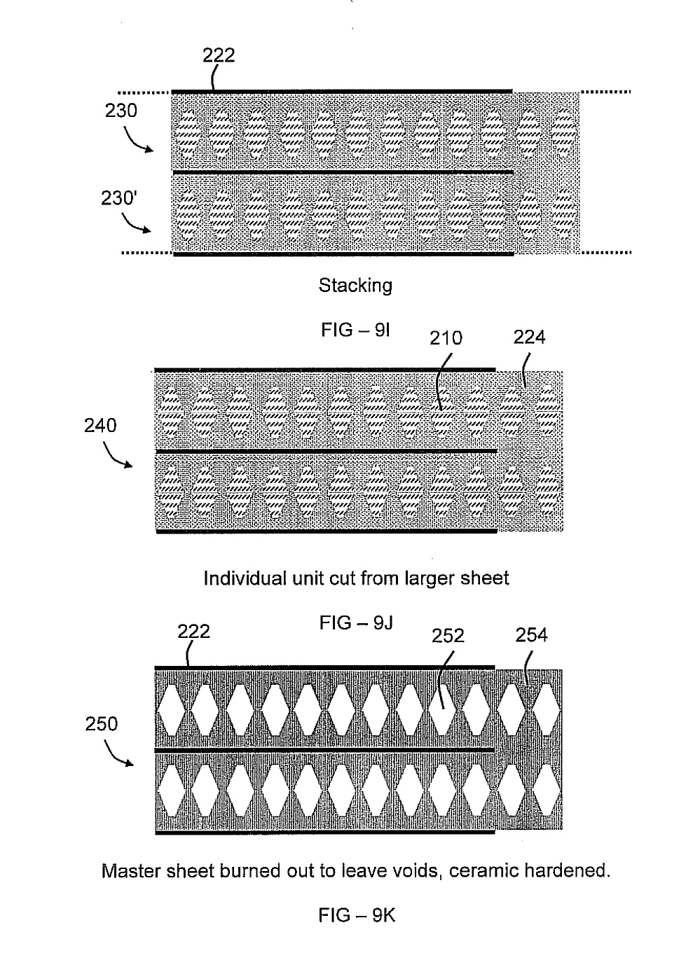

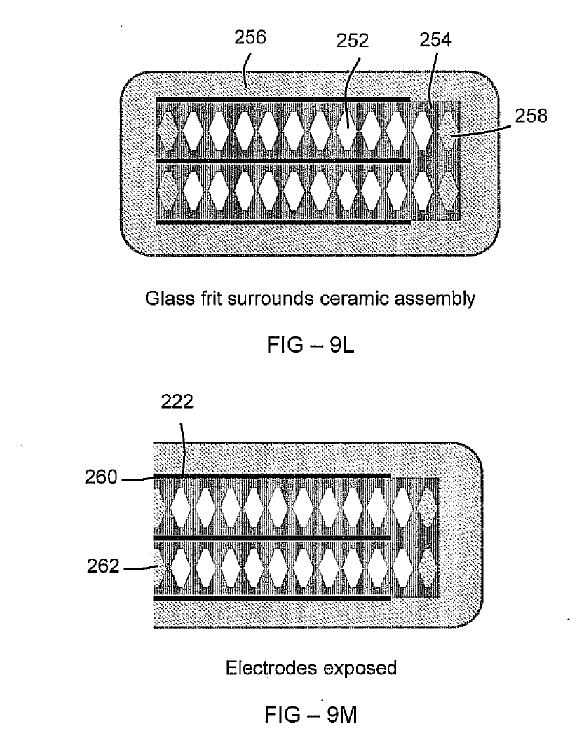

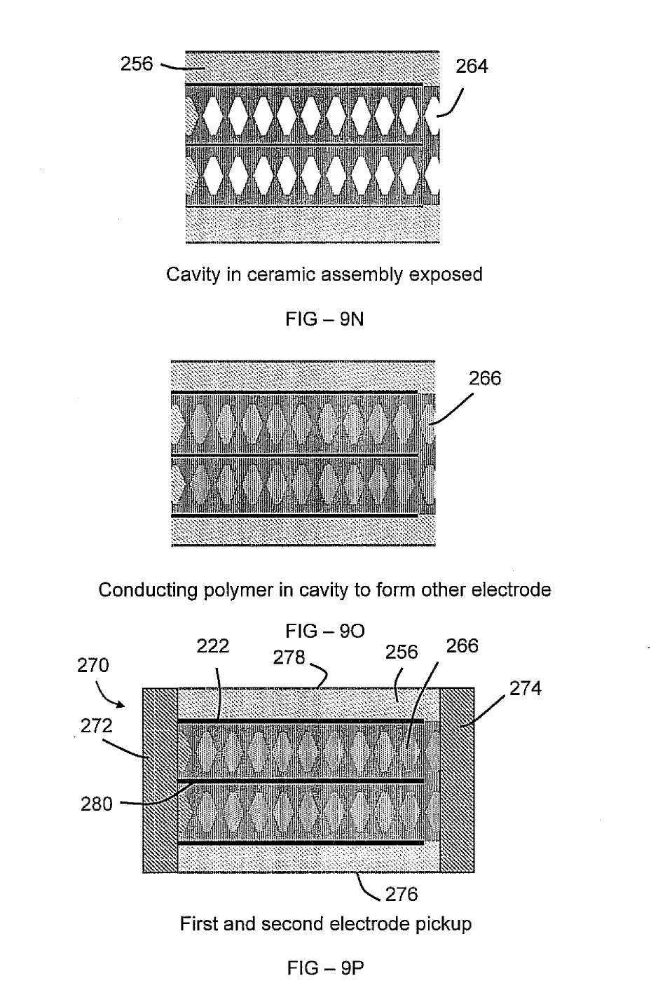

FIG. 9A-9P shows a schematic diagram of an array of ordered square pyramids. Commercially available precise ruling and cutting machines can cut precise groove patterns in flat metal and polymer (plastic) sheets. This method was used to produce precise fine-scale patterns of ordered square pyramids such as shown in FIG. 9A. The results of direct machining are good, particularly at larger scales, but a cutting approach is time consuming and expensive when applied to hard ceramic materials. Any milling, sawing, or similar approach may be used. For example, sub-micron sawing of truncated pyramids or cones may be achieved in a plastic sheet using a conventional sawing apparatus, and these features may be transferred to a hard ceramic using the approaches described herein.

Embodiments of the present invention include using a process (such as cutting) to produce a master structure which can be replicated inexpensively in a ceramic precursor such as a green ceramic. A green ceramic is typically one including organic materials, for example a slurry of inorganic particles with an organic binder, which can be converted to a finished ceramic material, for example by heating to remove the organic components and/or sintering.

Green ceramic materials and ceramic processing are described in U.S. Pat. Nos. 5,234,641, “Method of making varistor or capacitor”; 4,353,957, “Ceramic matrices for electronic devices and process for forming same”; and 4,071,880, “Ceramic bodies with end termination electrodes”, all to Rutt.

An example assembly process for a flexoelectric multilayer ceramic is as follows:
1. Cut master masks
2. Align master masks to produce negative mold
3. Inject hard polymer into mold
4. Unclamp master sheet
5. Tape cast ultra soft BST green ceramic sheets
6. Screen print electrodes
7. Insert negative polymer casting between green sheets and press to form monolithic unit.
8. Stack monolithic green sheets to achieve required final thickness
9. Cut up sheet following electrode pattern to shape of final green units.
10. Burn out binder and polymer inserts in flowing oxygen, then fire the units
11. Coat the units with glass frit
12. Grind off glass frit to expose electroded end
13. Grind off glass frit to expose cavity end
14. Vacuum impregnation conductive polymer into cavity structure
15. Pick up of polymer electrode on both sides of the units

An example process uses two master grooved plates cut to the required scale, then mounting them rigidly face to face to produce a mold for the negative of the surface required. The opposed faces may be coated a thin film of a parting compound. The mold is back filled with monomer (or other material from which a replica can be formed) so as to form a rigid polymer replica which, when set, can be released by unclamping the sheets. The procedure can be repeated to produce a large number of negative replicas at the scale required.

To transfer the pattern to ceramic, soft green sheets of a ceramic material (such as barium strontium titanate) of the required thickness are tape cast, and electrode patterns of the required scale for the actuator screen are printed onto one surface of the green ceramic sheet. In an example approach, only the upper electrode has the overlap necessary for edge pickup. Two single-electroded green sheets, with the bottom sheet inverted, are precisely positioned so that the electrodes juxtapose. A negative replica, such as a negative replica of truncated pyramid shaped elements, is placed in between the two green sheets. The green sheets are then cold pressed together to completely fill the space around the negative replica.

The tape is now cut into precisely located tablets which are stacked to produce (after firing) the required transducer thickness. The stacked tape can now cut to release each separate actuator. In an example approach, both electrodes project from the same side and the edges are revealed by the cutting. Binder burn-out in flowing oxygen is arranged so that the plastic negative replica is burned out at the same time as the ceramic binder, then the units are fired to generate the stress concentrating micro-cavity structure.

The fired actuator can be coated with a very thin layer of an insulating glass frit. For example, viscosity on firing can be adjusted so that it just penetrates approximately 0.1 mm into the cavity structure. To access the metal electrodes, this frit is ground off the electrode protruding edge to reveal the electrodes but not to penetrate the cavity structure and the electrodes can then be picked up.

To provide the counter electrode, the insulating frit may be sufficiently ground off the opposite face to the emergent electrodes so as to open the cavity structure. The cavity structure can be back filled by vacuum impregnation with a soft polymer conductor, which can fill all micro-cavities.

FIG. 9A shows a mask 200 in the form of an array of a square truncated pyramids 202 on a planar substrate 204. In other examples, the mask may comprise other pyramidal forms (optionally truncated) with different base geometries, frusto-conical shaped elements, cones, and the like.

The truncated pyramids 202 (or other forms, such as cones) may be micron-scale, for example having base side lengths and/or heights in the range 0.1-100 microns, In other examples, other shaped elements or dimensions may be used. The mask may be formed in any convenient material, such as a plastic. Hence, conventional precision milling or sawing machines may be used, and the problems of machining hard ceramic materials can be avoided.

FIG. 9B shows a cross-sectional view of mask 200, showing the eventual shape of the piezoelectric-ferroelectric elements (here, truncated pyramids 204) in cross-section. Other example shaped elements are possible.

FIG. 9C shows a cross-section of a mold formed by a pair of masks 200 and 200′. An appropriate parting compound may optionally be used. The opposed inner faces of the mask can be covered by a thin layer of parting compound.

FIG. 9D shows a master sheet 208 formed in the mold formed by masks 200 and 200′. The master sheet can be unclamped from the mold after formation, and hardening if appropriate. For example, a monomer material may be injected into the mold, and subsequently polymerized so as to obtain a polymer master sheet. The mask comprises negative replicas of the desired stress-concentrating elements, for example at 208.

FIG. 9E shows the master sheet shown generally at 210 unclamped from the mold, comprising negative replicas such as 208. In this examples, the master sheet comprises a plurality of such negative replicas interconnected by surrounding material 212.

FIG. 9F shows a green ceramic sheet 220, which may be prepared using a doctor blade technique. Other ceramic precursors can be used, such as solid solutions, for example solid solutions of barium strontium titanate.

FIG. 9G shows an electrode 222 formed on one surface of the green ceramic sheet 220.

FIG. 9H shows a master sheet 210 between a pair of electroded green sheets 220 and 220′, having electrodes 222 and 222′ thereon, respectively. The electroded unit may be referred to as a tablet, indicated generally at 230.

FIG. 9I shows a stack of electroded units, in this case comprising two tablets 230 and 230′ discussed above in relation to FIG. 9H. Electrodes such as 222 are present. In other examples, a device may comprise a single tablet, or a stack of greater than two tablets. The dashed lines extending laterally indicate that the illustrated structure may be part of a larger sheet.

FIG. 9J shows the tablets stacked preserving position of actuator units. A large sheet assembly may be cut to release smaller individual structure 240 as shown The structure 240 comprises a pair of negative replicas (such as 210) surrounded by green ceramic 224.

FIG. 9K shows the structure 250 after the structure 240 is fired to burn out binder, then fired to form densified ceramic. The negative replicas vanish during this process, leaving voids 252 surrounded by ceramic material 254. In this example, the voids are interconnected, though this is not shown in this cross-sectional view.

FIG. 9L shows coating the structure 250 with a glass frit 256. Other insulators may be used, and this step may be modified or omitted. The voids 252, ceramic 254, and included electrodes are surrounded by insulator, in this example the glass frit 256. There may be minor ingress of insulator into peripheral voids, as shown at 258.

FIG. 9M shows exposing electroded end. The end 260 of electrode 222, and other electrode ends, are revealed. Peripheral voids filled with insulator, e.g. 262, may be allowed to remain.

FIG. 9N shows exposing the cavity end. Insulator-filled voids (such as 258 in FIG. 9L) are removed, exposing the voids such as 264.

FIG. 9O illustrates vacuum impregnation of a conductive polymer 266. The conducting polymer fills the voids and allows electrical communication with the sloping sides of the pyramidal ceramic elements. Vacuum impregnation may be facilitated by sealing peripheral voids away from the filling end, if necessary. The structure may be vacuum filled with a monomer (or oligomer), with in-situ polymerization. Other conducting media may be used instead of conducting polymer, such as a metal (for example by introducing a molten metal into the voids).

FIG. 9P illustrates pick up of the conductive polymer electrode using first pick-up electrode 274, and pick up of the electrodes such as 222 using a second pick-up electrode 270. The final device is indicated generally at 270. The upper and lower surface of the material, as illustrated, may correspond to generally planar and parallel outer surfaces. For actuator use, electrical signals applied to the pick-up electrodes may induce an increase or decrease in these separation of these outer surfaces. For sensor use, a force may be detected using electrical signals from the pick-up electrodes.

The conducting polymer filled regions 266 define shaped elements within the ceramic. In this example, on each side of the central electrode, an array of pyramids oriented upwards (as illustrated) abuts an array of pyramids oriented in the opposite direction (downwards). In this example, the firing process may fuse the tops of the opposed shaped elements.

FIG. 9P can represent the cross-section of a material or apparatus having a generally cuboid form, with parallel, planar outer surfaces 276 and 278. In this configuration, layers of shaped elements are disposed each side of a generally planar central electrode 280. In other examples, a device may be formed from a single assembly as shown in FIG. 9H, or a greater number of such assemblies stacked together. One or both of the outer surfaces 276 and 278 may be used as, or support, force (e.g. vibration) receiving surfaces (e.g. for sensor applications), or other actuator components in actuator applications.

An apparatus may further comprise a charge storage device, electronic control unit, and the like.

A very wide range of variants on this tape casting method are clearly possible, and steps may be modified or omitted. Further possible aspects are discussed below.

The structure shown in FIG. 9P may correspond to two layered arrays of truncated pyramids (or other shaped elements) on each side of the central electrode.

For very high quality (high Q) units, metal (e.g. platinum) wires can be laid into the original negative image polymer and fired into the structure so as to facilitate high conductivity paths into the conductive polymer electrode (or other electrode used).

Series parallel pickup combinations can be used to generate higher electrical impedance whilst maintaining the strong composite flexoelectric piezoelectric effect.

By deliberately matching elastic properties of the two phases but mismatching dielectric properties, or by matching dielectric properties while mismatching elastic properties, actuators can be fabricated which do not sense and stress sensors can be fabricated which will not actuate. In this context, a mismatch may correspond to dielectric or elastic constants that differ by at least one order of magnitude.

Since both elastic and dielectric properties can have controlled frequency dispersive character, matching can occur at a specific frequency to get a new type of filter effect, such as frequency tunable actuator and/or sensor operation. For example, dielectric (or elastic constant) dispersion in one or both materials may result in a desired match (or mismatch) at a particular operational frequency. A single device may have a plurality of operational modes, e.g. sensor only, actuator only, different sensor sensitivities, different actuator distances, and the like, according to chosen operational frequencies (mechanical and/or electrical).

Soft mode ferroelectricity in perovskite structure oxides is believed to persist down to nanometer scale. If flexoelectricity persists over a similar range, the enhanced range of a modified tape casting process can be used to produce sub-micron scale structures with immense piezoelectric capability, substantially greater than can be obtained using conventional PZT materials.

In other examples, as mask may be used to form a template in a conducting material, such as a conducting polymer, and a green ceramic formed in the desired ceramic shape using the template.

Any templating method, including stamping or other replication process, may be used to form a desired shape in a ceramic precursor such as a green ceramic. Treatment of the ceramic precursor then provides a ceramic material having the desired shape and elastic properties. An electrode may then be deposited on the ceramic, conducting material used to fill voids, or other method used to obtain and/or apply an electrical potential.

Examples of the present invention include any piezoelectric device having a central electrode located between first and second layers of piezoelectric material (one or both of which may be a piezoelectric ferroelectric material). In an example configuration, a stress is applied between two outer surfaces, and potential formed at the central electrode relative to first and second electrodes on each side thereof.

Any templating process may be used to shape a ceramic precursor, such as molding, stamping, and the like. A ceramic precursor may be shaped by cutting, or other material removal process such as ablation and the like. After shaping the ceramic precursor, a firing process may be used to obtain a shaped ceramic. The shaping of the ceramic precursor may allow for subsequent dimensional changes on firing. A template may be formed in a fugitive phase, that is subsequently burned out after shape replication. Alternatively, a template may become part of a device, for example as part of an electrode or stress application surface.

Stress may be applied between two substantially planar and parallel surfaces, with a central electrode used to collect charge from two active layers. Tape casting allows good bonding between a ceramic precursor, in this case a green ceramic with organic components, and the stress application surfaces. A central electrode may act as a further mirror plane in the device symmetry, at least in respect to shaped ceramic components.

### Antipolar Devices and Resonant Frequencies

Devices may be configured to have mechanical resonances in frequency ranges of interest. The softer component (such as the conductive polymer discussed in relation to FIG. 9) may not make a substantial contribution to the resonant properties. Devices according to embodiments of the present invention can be better matched to mainly liquid media, for example for medical ultrasound applications, marine applications, and the like.

An electrode may comprise a relatively soft (compared to a ceramic material) conducting polymer, for example in contact with those parts of the shaped ceramic (or other material) having a stress gradient. The electrode may have little appreciable effect on resonant properties

In some examples, a stress bolt or similar structure may be used to keep a device (such as shown in FIG. 9 or other figures) in continuous stress. The applied stress can be chosen so that the device never goes into strain in normal operation. Even for a signal of maximum tension, the flexoelectric piezoelectric may remain in mild compression.

The number of layers of shaped elements is not limited. For examples, an apparatus may include more than 10, or more than 100 of such layers. Each layer may comprise a single layer of shaped elements in the same direction (which may alternate between layers), Layers may be separated by planar electrodes, or in some cases may not be so separated. In some examples, the structure is of the form: layer of shaped elements, layer of shaped elements in an opposite direction, planar electrode sheet, and this arrangement may be repeated.

Examples of the present invention include what can be termed “antipolar” devices. In conventional monolithic piezoelectric materials, the center of mass of a piezoelectric material moves slightly in response to an applied field or varying stress. There can be appreciable mechanical coupling with external elements, in particular to stress clamp. These effects may appreciably lower the resonance frequency, and reduce device sensitivity.

In the example shown in FIG. 9, the presence of truncated pyramids (frustrums) oriented in opposite directions allows an antipolar device to be realized. The truncated pyramids are oriented so that the central axes (through the middle of the larger area base) are generally parallel, and the relative orientations between adjacent layered arrays of the pyramids are inverted, corresponding to a rotation through 180 degrees.

In other examples, the ceramic material may include shaped elements generally in the form of dipyramids and/or elongated dipyramids (e.g. base to base or otherwise), which may be truncated, e.g. as a bifrustum or elongated bifrustum.

By reversing the direction of stress gradient within different portions of the device, movement of the center of mass during device operation can be substantially eliminated.

### Other Aspects

Embodiments of the present invention allow the capabilities of PZT and other lead-based sensors and actuators to be matched and surpassed using non-lead containing materials. Hence, considering the toxicity of lead, it would be environmentally irresponsible to continue using such conventional devices.

In some examples, ceramic shaped elements may be formed with multilayer structures. This is readily achieved using tape casting. However, uniform composition shaped elements are useful. Extrinsic contributions, such as domain wall motion, may contribute to a response. In some examples, single crystal materials may be used.

The overall shape profile of the shaped elements may be uniformly tapered, such as a straight-sided pyramid. In this case, the stress gradient is likely to scale as the square of the height of the pyramid. A more uniform stress gradient may be achieved using tapered shaped elements such as pyramids and cones having a width proportional to the square root of height. In other examples, such as wedges, a dimension may appropriately vary so as to obtain a uniform stress gradient. However, any shape capable of exhibiting a shape-induced stress gradient on application of a stress may be used.

In other examples, self-assembly of suitable shaped materials may be used in the preparation of a flexoelectric piezoelectric device. A substrate may be patterned to receive shaped materials in a particular arrangement or orientation.

### Independent Control of Direct and Converse Piezoelectric Effects

As the charge separation is gradient driven, it is possible to design composites where uniform stress will drive large strain gradient leading to strong direct piezoelectric effects. However, in the same materials, a uniform field will not generate strong field gradients giving no converse piezoelectric effect.

In some examples, a uniform electric potential difference will generate strong electric field gradients, but a uniform stress will not generate large strain gradients, leading to a composite with strong converse piezoelectricity but no direct piezoelectric effect.

In some examples, piezoelectric materials are fabricated in which the piezoelectric response is generated by flexoelectric properties of a first material. The first material can be chosen so as to have large flexoelectric coefficient, and shaped elements for these first materials chosen so that when properly mutually oriented with respect to a second material, the material converts a uniform applied elastic stress (or electric field) into a strong internal electric field gradient (or elastic stress gradient) in the first material, which may be considered as the active flexoelectric phase.

The second material can be chosen to have a high compliance constant and a low dielectric permittivity relative to the first component. Resultant electric polarization due to applied stress (or elastic stresses due to applied fields) are summed to generate the piezoelectric effect resulting from the Curie group symmetry of the composite. If the dielectric properties of the first and second materials are matched, under a uniform electric field applied to the composite, no electric field gradient will occur in the flexoelectric component; thus no flexoelectric stress will be generated, and consequently no converse piezoelectric effect will appear in the composite. However, if the elastic properties of the two component phases are simultaneously drastically mismatched, then under a uniform elastic stress applied to the composite, a strain gradient will appear in the flexoelectric component that will generate an electric polarization, and consequently the direct piezoelectric effect will appear in the composite.

A piezoelectric material according to embodiments of the present invention allows independent control of direct and converse piezoelectric effects. Hence, devices may be configured to show the direct effect but not the converse effect, or vice versa, or any desired combination of direct and converse effect magnitudes. Hence, devices according to the present invention include sensors that do not actuate, unlike any conventional piezoelectric sensor, and actuators that do not sense. This is a very useful separation of functions that allows novel smart materials to be designed. Independent control of direct and converse effects allows design of new smart materials for acoustic signature and vibration control. Compact highly active piezoelectric composites facilitate new MEMs applications in robotics and unmanned vehicles.

Examples of the present invention include a new technique for the fabrication of self-aligning high gradient micro-pyramid structures for macro-scale flexoelectric piezoelectric composites.

For sensor-only applications (converse effect only), a composite may be made from components having similar elastic constants, but different dielectric properties. For example, cones of a high dielectric material may be arranged in a low dielectric material.

Hence, for the first time, piezoelectric materials according to embodiments of the present invention may be designed to provide sensing without actuation, or actuation without sensing. For the first time it will be possible to make piezoelectric sensors which will not actuate and piezoelectric actuators which will not sense. These are useful for smart system applications and noise control. Either the piezoelectric effect only, the converse piezoelectric effect only, or both can be obtained using suitable material choices.

### Frequency and Temperature Dependent Effects

The direct and converse piezoelectric effects for a flexoelectric piezoelectric composite are influenced by temperature and frequency effects of permittivity and elastic properties. Hence, a material may be designed that shows only the one effect at a predetermined temperature or frequency, and the other effect (or combination of effects) at a second temperature or frequency.

For example, at frequencies above dielectric relaxation of a first component, the permittivity may then match that of a second component, so that no converse piezoelectric effect is observed from a composite.

For example, at temperatures above a glass transition, melting transition, or other transition of one component, elastic mis-match of two components may be achieved (or removed), allowing a strong direct piezoelectric effect (or elimination of such effect).

Other examples will be apparent to those skilled in the art.

### Further Examples and Discussion

Embodiments of the present invention include piezoelectric composites that do not include a centrosymmetric material, or at least in which the piezoelectric effect does not arise from the piezoelectric properties of any single component.

Examples include composites of two or more components, including a first material and a second material. The first and second materials have an interface inclined at an oblique angle to the direction of applied force or obtained electric field. In some examples, the first material is in the form of (shaped element comprising) a cone, frustoconical shape, pyramid, truncated pyramid, triangular prism, other geometrical or non-geometrical shape, or mixture thereof. There may be one or more such shaped elements in the composite material, for example having a taper in the direction of an applied force and/or electrical field. In some examples, the shaped elements are oriented, generally in parallel or antiparallel directions, and/or are arranged in a regular array.

The term “composite”, as used here, includes composites where the second material is air, so that there is only a single solid component, that is shaped as desired. The desired shaped elements may be formed by molding, cutting, or other physical, chemical, and/or mechanical process. Deformation of a multi-component composite after formation may be used to obtain or improve desired interface orientations.

In other examples, composites may comprise two or more solid dielectric materials. Other combinations are possible, including solid/solid, solid/gas, solid/liquid, and solid/liquid crystal. Solids include crystalline, amorphous, ceramic, glass, polymer, or other materials. One or both materials may be porous, or otherwise contain voids. Example materials, such as ceramic materials, include strontium titanate, barium titanate, barium strontium titanate, other titanates, other oxides, Z5U dielectrics, Y5V dielectrics, and ultrafine grain dielectrics.

A composite material may be sandwiched between parallel plates, such as electrically conducting plates, an electrical potential being obtained between the plates when a stress is applied normal to the plates. An electrical field can be obtained even where the composite is entirely centrosymmetric and there are no stress gradients in the externally applied stress. The composite may include a plurality of shaped elements of a first material dispersed through a second material. The composite may include two or more components.

In some embodiments, the composite includes at least two materials that are two materials are elastically dissimilar, such as an elastic modulus one or more orders of magnitude different. The two materials have an interface configured so as to generate a flexoelectric electric field having a component along a desired direction.

In other examples, a piezoelectric device may be formed by a material according to the present invention between a pair of substrates. The substrates may be metal plates, electrode layers, or other electrically conducting materials, for example as previously described, or one or both may be non-conducting. Separate components may be used for application of pressure to a device, and collection of electrical signals. There may be a conducting layer disposed on e.g. the surfaces of cones or pyramids of the first material at which the electric potential is developed.

The angle of the sloping sides, e.g. the cone angle of conical shaped elements, relative to the direction of applied force or field may be adjusted to maximize the desired signal while allowing stress propagation, e.g. from one layer to another. The optimum angle depends on the materials used.

At present, lead zirconate titanate (PZT) is superior to other ceramic piezoelectrics, and dominates commercial applications despite the lead content. At present, there is no competitive conventional lead-free competitor. However, embodiments of the present invention include lead-free composites with piezoelectric properties comparable to PZT.

Further, PZT does not retain its excellent properties in thin film form. In contrast, flexoelectrics are gradient driven and improve as they become thinner. Composites according to embodiments of the present invention are excellent for MEMS and high frequency ultrasound applications.

In conventional materials, direct and converse effects are thermodynamically equivalent and are always equal. In the gradient driven systems, strain and field gradients can be independently tailored to break the thermodynamic equivalence. Hence, direct, converse, or some combination of effects are achievable.

### Applications

Applications include: improved materials for sonar and medical ultrasound systems; fine scale composites that are particularly appropriate for high frequency ultrasound; smart systems able to make use of independent control of direct and converse effects, such as active systems for acoustic stealth; high activity MEMs systems; miniaturized control for unmanned vehicles; composites with piezoelectric constant orders of magnitudes greater than conventional materials arising from new artificial symmetries; chemistry on a chip applications; an improved fingerprint scanner; sonar applications; miscreant control devices; and improved piezoelectric transducers and loudspeakers.

Example applications further include sensors, in particular vibrational and acoustic sensors such as hydrophones, that can resist forces, such as explosive forces, that may destroy conventional sensors. For example, in examples of the present invention, voids between ceramic materials may close (a soft phase such as a conducting polymer may be driven out), so in the limits of high forces a sensor may approaches a monolithic ceramic. As such, at the limits of high forces a device may be highly resistant to damage. This may result from non-linear elastic response to forces above a certain threshold, depending on the material. After a force is removed, voids open out again and device operation may continue. In such examples, shaped ceramic elements may be separated by voids, and the shape and configuration of voids may be calculated with reference to material elastic constants so that the voids are closed by forces greater than a design threshold. Electrodes may be metallized films on the tapered portions of the shaped elements.

Applications further include methods and apparatus for energy scavenging. For example, vibrational energy may be converted to electrical energy and stored in a battery, for example electrically connected to the pick-up electrodes of FIG. 9P. The mechanical input impedance can be very high, compared with conventional devices, due to the high elastic constants of ceramic materials that may be used. The electrical output impedance may be relatively low, with power out to an electrical storage device such as a battery, fuel cell, or storage capacitor. There is no need for an output transformer to reduce the electrical output impedance.

The pick-up electrodes may be configured to connect the electrical signals from shaped elements into series or parallel electrical configuration. For example, in the example of FIG. 9P, the pick-up electrode configuration is parallel, and the output voltage may correspond to that generated by a single truncated pyramidal shaped element. However, current capability is increased by parallel electrical configuration.

Pixel driven phased arrays in high frequency ultrasound need high power from small pixel elements. To get high power in at low voltage for simple CMOS control requires high dielectric permittivity. For PZT ∈ᵣ max˜3,000, whereas in (Ba,Sr)TiO₃, ∈ᵣ max˜20,000, a significant advantage for applications where high permittivity is desired.

Hence, an example flexoelectric piezoelectric composite has a piezoelectric response, which may be a direct piezoelectric effect and/or converse piezoelectric effect (such as both effects, or only one effect). An example flexoelectric composite comprises a first material, which may be substantially isotropic, the first material being present in a shaped form. The shaped form allows a piezoelectric response (an electric potential due to an applied stress) due to a flexoelectric effect in the first material, even if the first material is substantially isotropic. The shaped form allows a stress gradient to develop in response to an applied stress.

For example, a stress applied over a shaped form having a first surface having a first area and a second surface having a second area provides a stress gradient within the shaped form related to the difference between the first area and the second area, and the separation between the first surface and the second surface. A uniform stress gradient may be obtained if the cross-sectional area scales as height (such as the distance of the cross section from one of the surfaces). However, linearly tapered shaped elements and other tapered shaped elements may also be used. In a representative example, the first material has an elastic constant for deformation much greater than that of the second material, so that the stress is substantially entirely felt across the first material. For example, the first material may be a ceramic, and the second material a relatively soft material (in terms of elastic constant for deformation) such as a polymer. The second material may also be a fluid, such as air, a conducting liquid, other liquid, or other fluid. If the second material is non-conducting, an electrode layer can be used to collect the flexoelectric-generated potential from regions of stress gradient of the first material. The electrode layer may be a metal film.

Patents, patent applications, or publications mentioned in this specification are incorporated herein by reference to the same extent as if each individual document was specifically and individually indicated to be incorporated by reference. U.S. patent application Ser. No. 11/770,318 to Cross et al. is also incorporated herein by reference.

The invention is not restricted to the illustrative examples described above. Examples are not intended as limitations on the scope of the invention. Methods, apparatus, compositions, and the like described herein are exemplary and not intended as limitations on the scope of the invention. Changes therein and other uses will occur to those skilled in the art. The scope of the invention is defined by the scope of the claims.

Having described our invention, we claim:

1. A method for preparing an apparatus providing a flexoelectric-piezoelectric; response, the method comprising:
providing a template, the template including a negative replica of a shaped element;
forming a assembly including the template and a ceramic precursor, the shaped element being formed in the ceramic precursor using the template;
thermally treating the assembly so as to remove the template and to convert the ceramic precursor into a ceramic, removal of the template leaving a void in the ceramic; and
introducing a conducting material into the void so as to provide a first electrode in contact with the shaped element in the ceramic,
the shaped element within the ceramic generating a stress gradient in response to a force applied across the flexoelectric-piezoelectric device,
the flexoelectric-piezoelectric response being obtained using the first electrode.

2. The method of claim 1, the template being provided by:
forming a mask by precision machining a replica of the shaped element into a non-ceramic material;
forming a mold using the mask; and
forming the template using the mold, the template including a negative replica of the shaped element,
the shaped element being formed in the ceramic precursor using the template.

3. The method of claim 1, the shaped element including the form of a pyramid, truncated pyramid, cone, or truncated cone.

4. The method of claim 3, the template being a polymer template.

5. The method of claim 1, wherein the conducting material is a conducting polymer.

6. The method of claim 1, the ceramic precursor being a green ceramic sheet.

7. The method of claim 6, the ceramic green sheet having a first surface and a second surface, the second electrode being disposed on the first surface,
the method comprising urging the template urged into the second surface of the ceramic green sheet.

8. The method of claim 1, wherein thermally treating the assembly comprises firing the assembly so as to convert the ceramic precursor into a ceramic.

9. The method of claim 6, the template including a first side and a second side, the template including negative replicas of shaped elements on both the first and second sides,
the method comprising urging a first ceramic green sheet onto the first side of the replica and urging a second ceramic green sheet onto the second side of the replica.

10. An apparatus, the apparatus being a flexoelectric-piezoelectric apparatus comprising:
a first shaped element, configured so as to provide a first stress gradient when a force is applied to the apparatus; and
a second shaped element, configured so as to provide a second stress gradient when the force is applied to the apparatus,
wherein the first stress gradient and second stress gradient are in opposite directions,
the first and second shaped elements both comprising a ceramic material having a flexoelectric coefficient,
so that a flexoelectric piezoelectric effect arises from the first and second stress gradients.

11. The apparatus of claim 10, wherein the first shaped element and second shaped element are selected from a group of shaped elements consisting of pyramids, truncated pyramids, cones, and truncated cones.

12. The apparatus of claim 10, wherein the first shaped element and second shaped element have a similar shape, the first shaped element and second shaped element having a relative orientation direction of approximately 180 degrees.

13. The apparatus of claim 12, comprising:
a plurality of first shaped elements, and
a plurality of second shaped elements.

14. The apparatus of claim 13, wherein the number of first shaped elements is approximately equal to the number of second shaped elements.

15. The apparatus of claim 13, further comprising a central electrode located between the plurality of first shaped elements and the plurality of second shaped elements,
a first electrical contact in proximity to the plurality of first shaped elements, and
a second electrical contact in proximity to the plurality of second shaped elements.

16. An apparatus, the apparatus being a flexoelectric-piezoelectric apparatus comprising:
a first plurality of shaped elements;
a second plurality of shaped elements;
a central electrode located between the first plurality of shaped elements and the second plurality of shaped elements;
a first conducting material in proximity to the first plurality of shaped elements; and
a second conducting material in proximity to the second plurality of shaped elements,
the apparatus having a pair of generally parallel outer surfaces,
wherein the shaped elements are configured so that a compression applied between the pair of generally parallel outer surfaces induces stress gradients within the first and second plurality of shaped elements,
the shaped elements comprising a ceramic.

17. The apparatus of claim 16,
the first plurality of shaped elements including shaped elements having a first orientation and shaped elements having a second orientation, the first orientation being rotated 180 degrees relative to the first orientation.
